(19) United States
(12) Patent Application Publication
(10) Pub. No.: US 2024/0036825 A1
(43) Pub. Date: Feb. 1, 2024

(54) SCALAR PRODUCT CIRCUIT, AND METHOD FOR COMPUTING BINARY SCALAR PRODUCTS OF AN INPUT VECTOR AND WEIGHT VECTORS

(71) Applicant: Robert Bosch GmbH, Stuttgart (DE)

(72) Inventors: Andre Guntoro, Weil Der Stadt (DE); Taha Ibrahim Ibrahim Soliman, Renningen (DE); Tobias Kirchner, Ludwigsburg (DE)

(21) Appl. No.: 18/245,843

(22) PCT Filed: Sep. 16, 2021
(86) PCT No.: PCT/EP2021/075407

§ 371 Date: Mar. 17, 2023

(30) Foreign Application Priority Data
Sep. 22, 2020 (DE) 10 2020 211 818.3

(51) Int. Cl. G06F 7/523; G06F 7/50; G06F 17/16; G06F 5/01; H03M 1/12

(52) U.S. Cl. CPC G06F 7/523; G06F 7/50; G06F 17/16; G06F 5/01; H03M 1/12

(57) ABSTRACT

A scalar product circuit for computing a binary scalar product of an input vector and a weight vector. The scalar product circuit includes one or multiple adders and at least one matrix circuit including memory cells that are arranged in multiple rows and multiple columns in the form of a matrix, each memory cell including a first memory state and a second memory state. Each matrix circuit includes at least one weight range including one or multiple bit sections, the matrix circuit including an analog-to-digital converter and a bit shifting unit connected thereto for each bit section, the column lines of the bit section being connected to the analog-to-digital converter, and a column selection switching element being provided for each column. The bit shifting units are connected to one of the adders, those bit shifting units that are included in a weight range being connected to the same adder.

### FIELD

The present invention relates to a scalar product circuit and a method for computing binary scalar products of an input vector and weight vectors, an associated module, as well as a processing unit and a computer program for carrying out the method.

### BACKGROUND INFORMATION

In many computationally intensive tasks, in particular in artificial intelligence applications or machine learning applications that use neural networks, scalar products of vectors are determined. For example, the convolutions in a convolutional neural network, referred to below as CNN, are scalar products of vectors. To carry out such vector operations quickly and efficiently, vector-matrix multipliers in the form of electronic circuits specifically provided for this purpose are used.

In these vector-matrix multipliers, also referred to as “dot-product engines,” a vector of input voltages is converted into a vector of output voltages using an arrangement of memristors in the form of a matrix, which are situated at intersection points of mutually orthogonally extending lines and which connect the intersecting lines in pairs, the output voltages in each case being proportional to the scalar product (“dot product”) of the vector of the input voltages and the conductivities of the memristors situated in a column. The input voltages are applied to the row lines extending in one direction, and result in currents, across the memristors, into the column lines that extend orthogonally thereto and that are connected to a ground potential. The currents are converted into the output voltages with the aid of transimpedance amplifiers. Such circuits may in each case reach values of several hundred or several thousand rows and columns.

### SUMMARY

According to the present invention, a scalar product circuit and a method for computing binary scalar products of an input vector and weight vectors, an associated module, as well as a processing unit and a computer program for carrying out the method, are provided. Advantageous embodiments of the present invention are disclosed herein.

The scalar product circuit according to an example embodiment of the present invention or the associated method employs the measure of providing weight ranges in the matrix circuits which include bit sections for each bit of a weight element, which are stored in the memory cells of a column of the bit sections. The first and second memory states correspond to the two possible values of a bit. The bits of the input elements of the input vectors may be applied to the row line, voltages of 0 V or that correspond to the predetermined voltage value in turn corresponding to the two possible values of a bit. The currents generated in the column lines or their current intensity are/is determined by the analog-to-digital converters as a binary value, and are/is shifted by the bit shifting units corresponding to the values of the bits of the weight elements and of the bits of the input elements, so that with a subsequent addition by the adders, an arithmetically correct value for the scalar product of the input vector and the weight vector is obtained as a binary value.

By use of the present invention, the problems associated with analog vector multiplication, in conjunction with the problems explained in greater detail with reference to FIGS. 1A and 1B, in particular inaccuracies in the computation, are avoided in that a digital computation is carried out based on binary weights and vectors, and only the formation of summed currents in the column lines takes place in an analog manner. A further advantage is that analog-to-digital converters with relatively few bits may be used (3-bit analog-to-digital converters, for example), which allows a simple design of the analog-to-digital converters. In addition, no digital-to-analog converters, which generate corresponding voltages that are proportional to the input vectors that are normally present as a binary value, are necessary.

Preferably at least one matrix circuit, more preferably all matrix circuits, include (s) multiple weight ranges. Regardless, at least one weight range, more preferably all weight ranges, include(s) multiple bit sections. In addition, likewise regardless of the number of weight ranges and/or bit sections, preferably at least one bit section, more preferably all bit sections, include (s) multiple columns.

Each of the memory cells is preferably configured in such a way that when the predetermined voltage value is present, the current intensity of the current that is conducted into the column line when the memory cell is in the second memory state is greater, by a multiple, than the current intensity of the current that is conducted into the column line when the memory cell is in the first memory state; the multiple is preferably at least 100, more preferably at least 1,000. Clearly distinguishable current intensity values at the column lines may thus be achieved.

According to an example embodiment of the present invention, each of the memory cells is also preferably configured in such a way that when the memory cell is in the first state, no current is conducted into the column line connected thereto. The memory cells thus allow the implementation of a logical AND operation.

The memory cells preferably include a memristor and/or a semiconductor switching element, in particular a ferroelectric field effect transistor or a field effect transistor with a floating gate. This allows the scalar product circuit to be manufactured using conventional technologies.

According to an example embodiment of the present invention, multiple matrix circuits are preferably provided, the bit shifting units from one weight range in each case being connected to the same adder in two or more of the matrix circuits. Scalar products of input vectors and weight vectors having a length that is greater than the number of rows of a matrix circuit may be computed in this way. For example, if a matrix circuit includes m rows, and the bit shifting units of weight ranges in k matrix circuits are connected to the same adder, scalar products of vectors having a maximum length of m k may be directly computed. If scalar products of even longer vectors are to be computed, for portions of the vectors it is possible for partial sums to be initially formed by the vector multiplication circuit and subsequently added. The weights for the various portions may be stored in various columns of the weight ranges.

According to an example embodiment of the present invention, a voltage generation element is preferably provided for each row line, and is connected to the row line and configured, as a function of a predefined input signal which may be present in two different value ranges, to generate a voltage of 0 V or a voltage having the predetermined voltage value and apply it to the row line. The two different values of the input signal correspond to the two possible values of a bit. Voltage generation elements are advantageous when the input signal has voltage values that are not suitable for direct processing by the matrix circuit or the memory cells (for example, excessively small or large voltages, or because the input signal within the value ranges has excessively large fluctuations).

According to an example embodiment of the present invention, the analog-to-digital converters are preferably configured to determine the binary values using 5 bits, preferably 4 bits, more preferably 3 bits or fewer. The analog-to-digital converters may be constructed with a simple design due to the small bit width.

A method according to an example embodiment of the present invention is provided for computing binary scalar products of one or multiple input vectors, each including binary input elements, and one or multiple predetermined first weight vectors, each including binary weight elements, using a scalar product circuit, including adders that correspond to the number of predetermined first weight vectors, one or multiple weight ranges situated in various matrix circuits of the scalar product circuit being assigned to each adder, each adder being connected to the bit shifting elements that are connected via the analog-to-digital converters to the bit sections included in the weight ranges assigned to the adder, including
A) assigning an adder to each first weight vector, and assigning the weight ranges that are assigned to the adder to the weight vector to which the adder is assigned;
B) storing the bits of the binary weight elements of the first weight vectors, for each weight vector the bits of the weight elements of the weight vector being stored in memory cells that are contained in each case in a column of a bit section of a weight range that is assigned to the weight vector, the bits of a weight element in each case being stored in a row, bits of various weight elements of the weight vector that have the same value and that are stored in the same weight range being stored in the same bit section of this weight range, and when a bit is stored in a memory cell, the memory cell being placed in the first memory state when the bit has the value 0, and the memory cell being placed in the second memory state when the bit has the value 1;
C) activating the columns in which bits of the weight elements of the first weight vectors have been stored;
D) for at least one of the input vectors:
a) setting the summed binary values of the adders to zero; b) for the bits of the input elements of the particular input vector having the same value, in each case:
   i) applying voltages corresponding to the bits to the row lines, voltages corresponding to the bits of various input elements being applied to various row lines, a voltage of 0 V being applied when the particular bit has the value 0, and a voltage having the predetermined voltage value being applied when the particular bit has the value 1;
   ii) determining binary values by the analog-to-digital converters;
   iii) shifting the binary values by the bit shifting units in order to obtain shifted binary values, the number of bits by which the binary value is to be shifted being predefined for each bit shifting unit, the predefined number of bits being determined as the sum of the value of the bits of the input elements, corresponding to which voltages are applied, and of the value of the bits of the weight elements that are stored in the bit section to which the particular bit shifting unit is connected via the analog-to-digital converter;
   iv) adding the shifted binary values by the adders;
c) reading out the summed binary values as first binary scalar products.

With the aid of the method according to the present invention, for example in a convolutional neural network (CNN), convolutions including multiple convolution kernels (corresponding to the number of first weight vectors) may be simultaneously computed in a layer.

According to an example embodiment of the present invention, the method preferably also encompasses computing second binary scalar products of the one or multiple input vectors and one or multiple predetermined second weight vectors which in each case include binary weight elements, the number of second weight vectors being less than or equal to the number of first weight vectors; including
E) assigning an adder to each second weight vector, and assigning the weight ranges that are assigned to the adder to the weight vector to which the adder is assigned;
F) storing the bits of the binary weight elements of the second weight vectors, for each weight vector the procedure corresponding to step B) being carried out, the bits of the weight elements of the two weight vectors being stored in columns that are different from the columns in which the bits of the weight elements of the first weight vectors are stored;
G) activating the columns in which bits of the weight elements of the second weight vectors have been stored;
H) for at least one of the input vectors, carrying out the substeps corresponding to step D), with the difference that in substep c) the summed binary values are read out as second scalar products.

If a neural network, in particular a CNN, includes multiple layers, the convolution kernels of the various layers may be stored as weight vectors in different columns of the same scalar product circuit.

A module according to an example embodiment of the present invention includes a scalar product circuit according to the present invention and a processing unit, connected thereto, that is configured to carry out all method steps of a method according to the present invention. Such a module or processing module may be used, for example, to speed up artificial intelligence applications that are based on neural networks. Such a module, for example in a computer, may be used, for example, as a plug-in module, or also in a control unit of a motor vehicle or of a machine.

A processing unit according to an example embodiment of the present invention is configured, in particular by programming, to carry out a method according to the present invention.

In addition, the implementation of a method according to the present invention in the form of a computer program or computer program product including program code for carrying out all method steps is advantageous, since this incurs particularly low costs, in particular when an executing control unit is also utilized for further tasks and therefore is present anyway. Suitable data media for providing the computer program are in particular magnetic, optical, and electric memories, for example hard disks, flash memories, EEPROMs, DVDs, and others. In addition, downloading a program via computer networks (internet, intranet, etc.) is possible.

Within the scope of the present patent application, the terms “connection,” “is connected,” and the like are to be understood in the sense of electrically conductive connections unless stated otherwise; for example, when a switching element is provided in a connection, the connection may be disconnected and reconnected.

Further advantages and embodiments of the present invention result from the description and the figures.

The present invention is schematically illustrated based on exemplary embodiments in the figures, and is described below with reference to the figures.

### BRIEF DESCRIPTION OF THE DRAWINGS

FIGS. 1A and 1B show a vector-matrix multiplier not according to the present invention.

FIG. 2 shows a weight range of a matrix circuit and an adder according to one preferred specific embodiment, which may be included in a scalar product circuit according to the present invention.

FIG. 3 shows a preferred scalar product circuit including multiple adders and a matrix circuit that includes multiple weight ranges, according to an example embodiment of the present invention.

FIG. 4 shows a preferred scalar product circuit including multiple matrix circuits according to an example embodiment of the present invention.

FIG. 5 shows the design of a memory cell that may be used for the present invention.

FIG. 6 shows a flowchart of a preferred method according to an example embodiment of the present invention.

### DETAILED DESCRIPTION OF EXAMPLE EMBODIMENTS

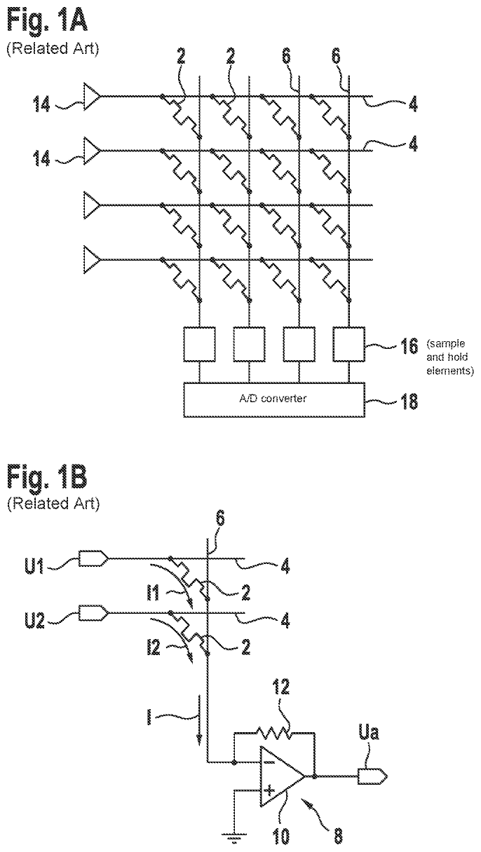

FIGS. 1A and 1B illustrate a vector-matrix multiplier, also referred to as a dot-product engine, not according to the present invention. The vector-matrix multiplier includes memory cells in the form of memristors 2 that are arranged in rows and columns in the form of a matrix. The number of rows and the number of columns are in each case arbitrary; a 4×4 arrangement is illustrated as an example. The memory function of the memristors results from the fact that the resistance of the memristors is adjustable by applying a programming voltage.

The vector-matrix multiplier also includes a row line 4 for each row of the arrangement in the form of a matrix, and includes a column line 6 for each column. Memristors 2 are situated at the intersection points of mutually perpendicularly extending row lines and column lines, and in each case connect a row line to a column line, which otherwise are not connected.

When voltages are applied to the row lines, currents flow from row lines 4, through memristors 2, and into column lines 6. This is illustrated for one column and two rows in FIG. 1B. In FIG. 1B, a voltage U1 is applied to one of the row lines and a voltage U2 is applied to the other row line. Current I1 through one of the memristors is determined by its conductivity G1: I1=G1·U1; current I2 through the other memristor, whose conductivity is G2, is correspondingly 12=G2 U2. The sum of the currents, i.e., total current I=I1+I2=G1·U1+G2 U2, then flows through column line 6. Formation of a scalar product of voltages U1, U2, regarded as a vector, at row lines 4 and conductivities G1, G2 of the memristors, regarded as a vector, in a column thus takes place, the total current being proportional to the result of this scalar product. Thus, based on the overall matrix arrangement, in principle a multiplication of the vector of the voltages by the conductivities of the memristors regarded as matrix elements takes place. For functioning of the circuit, the end of column line 6 is at a reference or ground potential, against which the voltages are measured.

The total current of each column is generally converted into an output voltage Ua with the aid of a transimpedance amplifier 8. Transimpedance amplifier 8, illustrated here by way of example and being conventional, includes an operational amplifier 10 whose inverting input is connected to the column line and whose noninverting input is at ground, and a resistor 12 via which the operational amplifier is provided with negative feedback, so that output voltage Ua is given as Ua=−R·I, where R is the resistance value of resistor 12. At the inverting input of operational amplifier 10, transimpedance amplifier 8 generates a so-called “virtual ground” which, due to the high open-loop gain of the operational amplifier (100,000, for example), differs only slightly from the ground potential (only approximately 50 μV, for example, when voltages U1, U2 are in the range of approximately 5 V), so that the ground potential (i.e., the virtual ground) is present at the end of the column line, as determined by measurement, as is necessary for the functioning of the circuit.

The voltages at the row lines are typically generated from digital signals with the aid of digital-to-analog converters 14. Likewise, the output voltages at the column lines are typically converted back into a digital signal with the aid of sample and hold elements 16 and an analog-to-digital converter 18. To achieve high accuracy and to allow a large value range for the input signals and output signals to be covered, digital-to-analog converters and analog-to-digital converters including a correspondingly large number of bits are thus necessary.

This circuit not according to the present invention has several disadvantages: The line resistances of the row lines or column lines between individual cells decrease the accuracy of the vector-matrix multiplication, since these line resistances, the same as the memristors, influence the intensity of the currents. In addition, a fairly high current in a column line results in a fairly large voltage drop along the column line, which results in inaccuracies, since the computation is based on the potential of a column line corresponding to the ground potential. This likewise applies to the row lines; the higher the current, the greater is the voltage drop along the row lines, so that the input voltages of individual memory cells are shifted. Furthermore, high energy consumption and associated waste heat may occur as a function of the weights. Relatively costly or complicated digital-to-analog converters and analog-to-digital converters are necessary. The larger the matrix, the greater are these disadvantages.

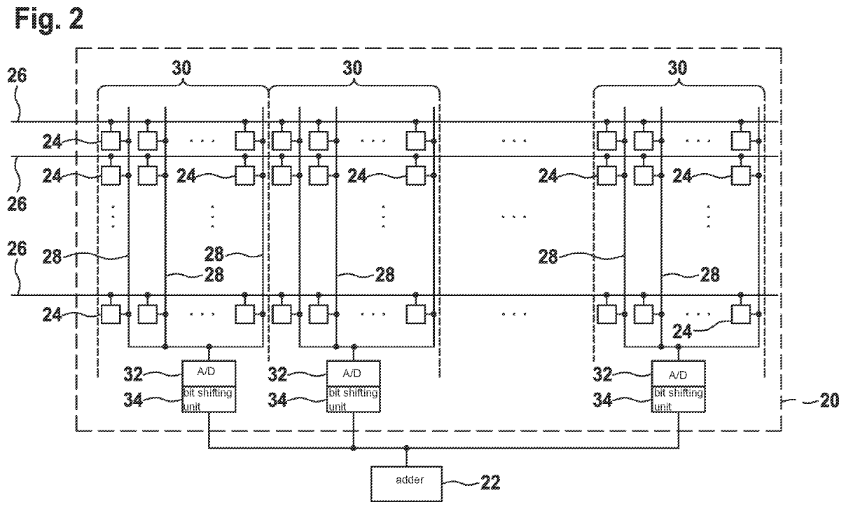

FIG. 2 illustrates a weight range 20 of a matrix circuit and an adder 22 connected thereto according to one preferred specific embodiment, which may be used in a scalar product circuit according to the present invention. Weight range 20 includes a plurality of memory cells 24 (of which only a few are representatively provided with reference numerals) arranged in rows and columns in the form of a matrix. Only a few of the memory cells included in weight range 20 are illustrated by way of example, illustrated memory cells 24 being situated in the first two rows and in the last row, and further memory cells being indicated by dots.

In addition, row lines 26 and column lines 28 of the matrix circuit that extend through weight range 20 are illustrated (here as well, only a few are representatively provided with reference numerals). The same as for the memory cells, once again only a few row lines (namely, the first two row lines and the last row line of the matrix circuit) and a few column lines of all row lines or column lines that extend through the weight range are illustrated. In general, a matrix circuit includes multiple weight ranges, the row lines extending through all weight ranges of the matrix circuit (i.e., are the same for all weight ranges of the matrix circuit), so that voltages applied to the row lines are present at the memory cells of all weight ranges connected thereto.

Each of memory cells 24 is connected to one row line 26 and to one column line 28, and is configured to conduct a current into the column line, the intensity of the current being a function of a memory state of the memory cell and a voltage that is present at the row line connected to the memory cell. The row lines are not directly connected to the column lines, and instead are connected only indirectly via the memory cells. Each memory cell includes two different memory states, a first memory state and a second memory state; when the voltage present at the row line that is connected to the memory cell is zero (0 V), regardless of whether the memory cell is in the first or the second memory state, no current is to flow (current intensity equals zero); i.e., no current flows or is conducted into the column line connected to the memory cell.

Weight range 20 is divided into multiple sections, each of which includes one or multiple columns or column lines. These sections are referred to as bit sections 30, three bit sections being illustrated in the figure as an example. Various bit sections 30 may include a different number of columns, it being preferred that all bit sections in a weight range have the same number of columns. In the figure, three columns are representatively illustrated in each bit section 30, and possible further columns are once again indicated by dots (of course, the number of columns in a bit section may also be less than three). The memory cells connected to a column line in the same bit section are configured in such a way that when they are in the second memory state, and a voltage having a predetermined voltage value not equal to zero is present at the particular row lines, the current conducted from each memory cell of the bit section into the particular column line has the same current intensity.

Preferably all memory cells of a bit section, more preferably all memory cells of a weight range, even more preferably all memory cells of a matrix circuit, most preferably all memory cells of the scalar product circuit, have the same design or the same properties; i.e., they have the same memory states, and the current intensity of the current that is conducted into the particular column line is in each case the same for the same memory state and the same voltage.

The memory cells, as in FIGS. 1A and 1B, may be implemented by memristors, for example, which in each case connect one row line to one column line. Memristors having a high on/off ratio are used; i.e., the conductivity of the memristor in the second memory state (on state) is much higher than the conductivity in the first memory state (off state), the on/off ratio thus being the ratio of the conductivity of the memristor in the second memory state to the conductivity of the memristor in the first memory state. As a result, when a voltage is present at the corresponding row lines, relatively little current is conducted into the column line by the memristors that are in the first memory state, and relatively little current is conducted into the column line by the memristors that are in the second memory state. The total current is then determined essentially by the number of memristors in the second memory state (and at whose row lines a voltage different from zero is present), a relatively small deviation (proportional to the on/off ratio) occurring due to the memristors in the first memory state (and at whose row lines a voltage different from zero is present). During the conversion into a binary value by the analog-to-digital converter, in principle rounding takes place, so that this deviation, provided that it is small enough, is not taken into account, and the binary value corresponds to the number of memristors in the second memory state, at whose row lines a voltage different from zero is present. The magnitude of the maximum allowable deviation is a function of the analog-to-digital converter, in particular its accuracy, i.e., the number of bits (or significant digits) of the binary value into which the analog-to-digital converter converts the analog current intensity value. In addition, it is to be taken into account that the number of bits of the binary value must be at least equal to the number of row lines of the matrix circuit plus one to allow all digitally different states to be differentiated.

The on/off ratio is preferably at least 100, more preferably at least 1,000, with an upper limit of approximately 10,000, depending on the technology of the memristors. Associated number N of bits of the analog-to-digital converter is preferably 5 or fewer (preferably 4 or fewer when the on/off ratio is in the range between 100 and less than 1,000), the maximum number of row lines of the matrix circuit being 2^{N}−1 in each case.

According to another preferred embodiment, the memory cells are configured in such a way that when the memory cell is in the first state, no current is conducted into the column line connected thereto, at least as long as the voltage present at the row line is in a predetermined voltage range that includes 0 V and the predetermined voltage value. This voltage range is determined by the configuration of the memory cell, and in a manner of speaking represents the working range of the memory cell, programming voltages outside this voltage range being used for typical memory cells. If the memory cell is in the second memory state, a current having a current intensity different from zero flows when the applied voltage is sufficiently different from zero, in particular when the applied voltage has the predetermined voltage value. In this way, the memory cells implement a logical AND operation between the memory state and the applied voltage, the first memory state corresponding to a logical 0, the second memory state corresponding to a logical 1, an applied voltage of essentially 0 V corresponding to a logical 0, and an applied voltage essentially not equal to 0 V, in particular having the predetermined voltage value, corresponding to a logical 1. “Essentially” here refers to the fact that corresponding voltage ranges may be present that are correspondingly interpreted, which once again depends on the precise configuration of the memory cells.

An implementation of corresponding memory cells that perform an AND operation may take place, for example, using semiconductor switching elements, including a (programmable) memory state, that switch between a conductive state and a nonconductive state as a function of a voltage that is present at a control connection of the semiconductor switching element and of the memory state. The control connection is then connected to the row line, an output of the semiconductor switching element is connected to the column line, and an input of the semiconductor switching element is connected to a power source, the semiconductor switching element switching the path between the input and the output between the conductive state and the nonconductive state.

In particular, ferroelectric field effect transistors (FeFETs) or floating gate metal oxide field effect transistors (FGMOSs) may be used as semiconductor switching elements. In both, the threshold voltage may be shifted by programming so that memory states may be implemented. For FeFETs, a ferroelectric material whose polarization shifts the threshold voltage is provided between the gate electrode of the FeFET and the source-drain path. The memory state corresponds to the polarization of the ferroelectric material. For FGMOSs, an isolated so-called floating gate, in which an electrical charge via which the threshold voltage is shifted may be stored, is provided between the gate electrode and the source-drain path. The memory state then corresponds to the stored charge. In both cases, the programming takes place by applying suitable (relatively high) programming voltages.

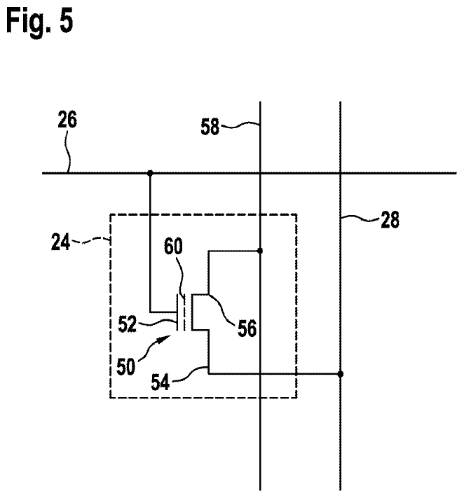

If field effect transistors (FETs) including various memory states are used, in particular FeFETs or FGMOSs, for each column, in addition to the column line a power supply line may be provided which is connected to a power source or voltage supply. FIG. 5 illustrates an example of the design of a corresponding memory cell 24: row line 26 is connected to gate 52 of FET 50, source terminal 54 of FET 50 is connected to the column line, and drain terminal 56 of FET 50 is connected to power supply line 58 of the column. A corresponding material layer 60 of FET 50 is used as memory for the memory states; reference numeral 60 denotes the ferroelectric layer for an FeFET, or the floating gate for an FGMOS. Memory states (polarization for a FeFET, charge in the floating gate for an FGMOS) are then determined as follows: in the first memory state the drain-source path is nonconductive, regardless of whether a voltage of 0 V or a voltage having the predetermined voltage value (5 V, for example) is present; in the second memory state the drain-source path is nonconductive when a voltage of 0 V is present, and is conductive when the predetermined voltage value is present, the current intensity of the current being the same for various FETs.

In FIG. 2, column lines 28 are connected to an analog-to-digital converter 32 that determines a binary value corresponding to a current intensity of the current flowing to the analog-to-digital converter, the column lines of a bit section being connected to the same analog-to-digital converter. For each column of the matrix circuit and in particular for each weight range of the matrix circuit, in each case a column selection switching element (not illustrated) is provided, via which the particular column may be activated. Only when the column is activated is a current provided by its column line to analog-to-digital converter 32, whose current intensity is determined by the voltages present at the row lines and the memory states of the memory cells situated in the column (i.e., the current intensity may also be zero, for example when all memory cells of the column are in the first memory state, or when a voltage of 0 V is present at all row lines). However, if the column is not activated, no current is provided by the corresponding column line.

The column selection switching elements may be implemented in various ways (also as a function of the design of the memory cells). For example, in the column lines in the connection between the memory cells and the particular analog-to-digital converter, switching elements may be provided which may separate and establish (or close) this connection; these may be semiconductor switching elements, in particular field effect transistors, whose control connection is activated via control lines to be correspondingly provided. In addition, a corresponding switching element may be provided in each memory cell, in which case the control connections of all these switching elements within a column are connected to a control line that is to be provided. If memristors are used, these switching elements provided in each memory cell may, for example, be connected in series with the memristors (i.e., for FETs the drain-source path is connected in series with the memristors). If FeFETs or FGMOSs whose drain terminal is connected to a power supply line provided in each column, as described above, are used as memory cells, switching elements (in particular semiconductor switching elements, for example FETs) that may separate and establish the connection of the power supply lines to the power source may be situated at the power supply lines. These options are merely examples; further embodiments of the column selection switching elements are likewise possible, depending on the design of the memory cells or the matrix circuit.

In the connection between the column lines and analog-to-digital converter 32, a transimpedance amplifier (not illustrated, cf. FIGS. 1A and 1B) may be provided which converts the current into a proportional voltage that is processed by the analog-to-digital converter. At the same time, such a transimpedance amplifier provides a reference potential or ground potential (virtual ground) at the column lines connected thereto, as described in conjunction with FIGS. 1A and 1B, against which the voltages (in particular the voltages at the row lines) are measured.

The transimpedance amplifier may also be regarded as part of the analog-to-digital converter. In general (within the meaning of the present patent application), an “analog-to-digital converter” is thus understood to mean a current intensity measuring element that determines the current intensity of an electrical current flowing at an input of the current intensity measuring element and outputs it as a binary value (in units determined by the analog-to-digital converter), a ground potential or a virtual ground at the same time being provided at the input. This ground potential is the reference potential on which voltages, in particular the voltages present at the row lines, are based.

In the specific embodiment in FIG. 2, in addition for each bit section a bit shifting unit 34 is provided which is connected to the particular analog-to-digital converter; i.e., the binary value determined by the analog-to-digital converter is passed on to the bit shifting unit. Each bit shifting unit 34 is configured to shift the bits of the binary value by a predefinable number of bits, the bits being shifted in a direction that arithmetically corresponds to a multiplication of the binary value by a power of two corresponding to the predefined number (i.e., if a shift is made by k bits, the binary value is multiplied by 2^{k}). After the bits are shifted, the binary value that is determined or output by the bit shifting unit is also referred to as a “shifted binary value.”

Bit shifting units 34 of weight range 20 are in turn connected to adder 22; i.e., bit shifting units 34 transfer the “shifted” binary values to adder 22. Adder 22 is configured to add up binary values that it receives, i.e., the shifted binary values that are transferred by bit shifting units 34, and to form a summed binary value.

When the scalar product circuit or the matrix circuit is used, i.e., during the computation of scalar products of input vectors and predetermined weight vectors, in each case the bits of a weight element of a weight vector given as a binary value are stored in each row of a weight range, in each case a bit of the weight element being stored in each bit section, i.e., in one of the columns of the bit section. The bits of various weight elements of a weight vector are stored in the same columns, each bit section corresponding to a certain value of the bits of the binary weight elements. In other words, for each weight vector in the bit sections, in each case exactly one column is provided, in whose memory cells the bits of the binary weight elements of the weight vector having a certain value are stored. The memory cells of a row in the columns assigned to the weight vector thus store the bits of a weight element.

“Storing a bit” means that when the bit has the value 0, programming of the first memory state is carried out in the memory cell, and when the bit has the value 1, programming of the second memory state is carried out in the memory cell. In the present context, a “vector” is a set or a tuple of multiple numerical values that are ordered in a sequence, each of these numerical values representing an “element” of the vector. As is customary, the sum over the products of mutually assigned elements from the two vectors, corresponding to their sequence, is referred to as the “scalar product” of two vectors having the same length (i.e., having the same number of elements).

The bits of further weight vectors that are assigned to a different layer of a CNN, for example, are stored in further columns of the bit sections.

During use, the columns assigned to a weight vector are initially activated (the columns not assigned to the weight vector are not activated). The bits of the input elements of the input vector are then applied to the row lines in sequence in multiple passes (corresponding to the number of bits of the input elements); i.e., a voltage corresponding to the value of the bit is generated and applied to the corresponding row line. When the value of the bit is 0, a voltage of 0 V is generated, and when the value of the bit is 1, a voltage corresponding to the predetermined voltage value is generated.

In each pass, each of analog-to-digital converters 32 determines a binary value that corresponds to the current intensity of the current in the particular column line (of which only one is activated in the bit sections). These binary values are shifted by bit shifting units 34 by the number of bits that are predefined for each of the bit shifting units in each pass; i.e., the bits of the binary values are shifted by the particular predefined number. The number, predefined for a bit shifting unit, by which the bits are shifted is equal to sum i+j of value i of the bits of the input elements, which are applied to the row lines in the particular pass, and value j of the bits of the weight elements that are stored in the bit section to which the bit shifting unit is assigned. Thus, in principle the binary value is multiplied by the factor 2^{i+j} to form the shifted binary value.

The “value” of a bit bᵢ of a binary value B that is described as follows (2-ary representation),

$$B = {\sum }_{i = 0}^{N} {b}_{i} {2}^{i} ,$$

where N is an integer greater than or equal to 0 and bᵢ may assume the values 0 or 1, is defined by index i.

In each pass the shifted binary values are transferred to adder 22, which adds them up within each pass and over the multiple passes to form a summed binary value, which after the last pass (i.e., after the last bits of the input vector have been applied) is the scalar product of the input vector and the weight vector. Prior to the first pass, the summed binary value in the adder should obviously be set to zero.

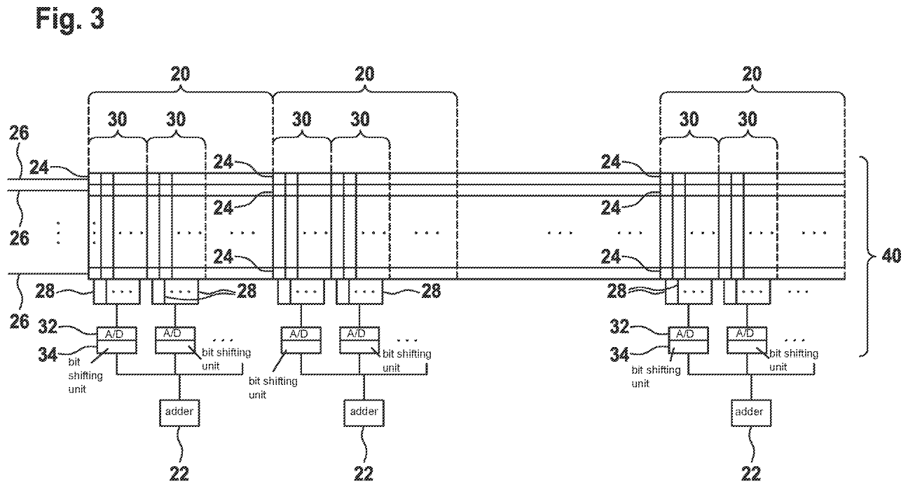

A matrix circuit preferably includes multiple weight ranges through which the same row lines extend. Thus, multiple weight vectors may be stored, and at the same time the scalar product with the same input vector may be formed. Each weight range is then connected to a different adder. This is illustrated in FIG. 3, explained below.

FIG. 3 illustrates a preferred scalar product circuit including multiple adders 22 and a matrix circuit 40 that includes multiple weight ranges 20. Memory cells 24 arranged in rows and columns in the form of a matrix are illustrated here merely as small squares, without illustrating their internal connections to row lines 26 and column lines 28 in detail. The same as in FIG. 2, once again only some of the elements are depicted by way of example, and further elements are indicated by dots, once again only some of the depicted elements being representatively provided with reference numerals.

Each of weight ranges 20 is designed as described in conjunction with FIG. 2, i.e., in each case includes one or multiple bit sections 30, each including one or multiple columns. Memory elements 24 are once again connected to a row line 26 and a column line 28, the memory cells functioning or being configured as described above. Row lines 26 and column lines 28 are indicated only at the edge of the matrix arrangement of the memory cells; however, these are to extend through the matrix arrangement (cf. FIG. 2). In particular, row lines 26 extend continuously through all weight ranges 20.

An analog-to-digital converter 32 (current intensity measuring element as described above) and a bit shifting element 34 connected thereto are assigned to each bit section 30, analog-to-digital converter 32 being connected to column lines 28 of bit section 30. The statements made in conjunction with FIG. 2 apply here as well. In particular, once again each column is activatable or selectable in a targeted manner by column selection switching elements, not illustrated. Bit shifting elements 34 of each weight range 20 are connected to an adder 22 which adds up the shifted binary values as explained above.

Each weight range 20 is thus designed as described in conjunction with FIG. 2, to each weight range an adder 22 being assigned that adds up the particular shifted binary values that are obtained from bit sections 20 or analog-to-digital converters 32 in conjunction with bit shifting elements 34 within particular weight range 20. The difference from the circuit in FIG. 2 is that multiple weight ranges 20, not just one weight range, are provided with respectively assigned adders 22 along column lines 26, so that multiple various weight vectors may be stored in the various weight ranges, and at the same time (i.e., the bits of the input vector need to be applied only once to the row lines), various scalar products (obtained as summed binary values at adders 22) of the weight vectors may be computed using the same input vector. This is helpful in convolutional neural networks (CNNs) in which a layer includes multiple so-called “feature maps,” each of which is obtained by convolution using various filter kernels (which correspond to the weight vectors).

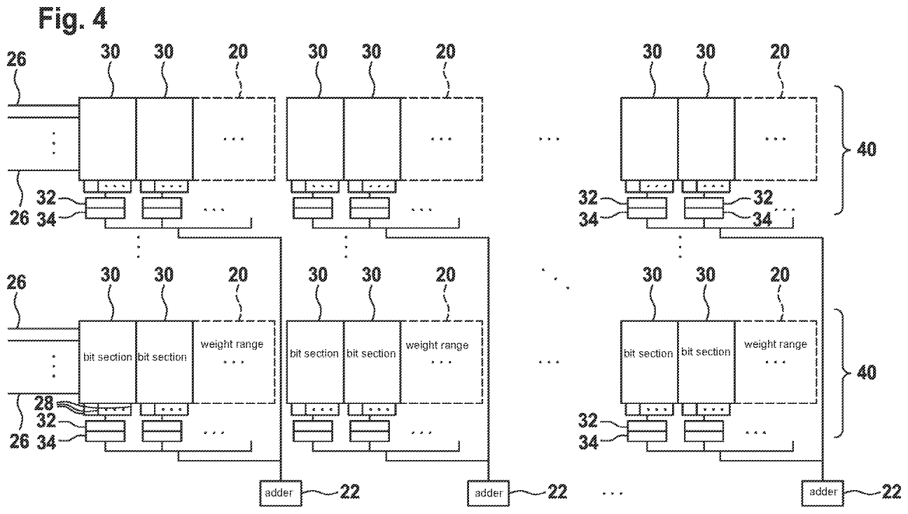

Analog-to-digital converters are preferably used with the fewest possible bits, in particular with only 4, 3, or 2 bits, which is advantageous since a simple design of the analog-to-digital converters is thus made possible. This implies that the corresponding matrix circuit is allowed to include only a limited number of rows in order to be able to differentiate between all possible different current intensity values at the row lines (for an n-bit analog-to-digital converter, the number of rows should be less than or equal to 2ⁿ−1). However, filter kernels used in CNNs (i.e., weight vectors) often include significantly more entries, for example several hundred or even more than one thousand entries. For their processing, a scalar product circuit including multiple matrix circuits may preferably be used, as shown in FIG. 4.

FIG. 4 illustrates a preferred scalar product circuit including multiple matrix circuits 40. Two matrix circuits 40 are illustrated as an example, in general it being possible to use even more matrix circuits (indicated by dots), for example even more than 10, more than 50, or more than 100, which are interconnected as illustrated, i.e., connected to adders 22.

Each matrix circuit 40 in FIG. 4 corresponds to the matrix circuit illustrated in FIG. 3, i.e., includes multiple weight ranges 20 (only one weight range is also possible, which would then be the matrix circuit in FIG. 2) including one or multiple bit sections 30 in each case. The statements made in conjunction with FIGS. 2 and 3 also apply here. Weight ranges 20 (which in each case include the dashed-line areas and the depicted two bit sections 30 in each case that are connected thereto) are illustrated slightly spaced apart in FIG. 4 for the sake of clarity and to allow depiction of the connections together with the adders in the two-dimensional figure. Row lines 26 extend through all weight ranges of a matrix circuit, even though they are indicated only at the left-hand edge in the figure. Such spacing is not necessary in an actual implementation in a chip, and is used here only to make the structure discernible.

The scalar product circuit includes multiple adders 22, in the present case it being important that each adder 22 is connected to bit shifting units 34 of multiple weight ranges situated in various matrix circuits, here with the bit shifting units in two weight ranges 20 in each case that are situated in the two matrix circuits 40. If more matrix circuits are present, an adder may be connected to the bit shifting units of (exactly) one weight range in each of the multiple matrix circuits. The connections are illustrated here as extending through the spaces between the weight ranges. In an actual implementation in a chip, the connections extend, for example, in a different level of the chip.

The weight elements of a weight vector that is too long for an individual matrix circuit may be divided over the multiple matrix circuits, the weight elements being stored in weight ranges that are connected to the same adder. The bits of the input elements of the input vectors are applied to the corresponding row lines of the multiple matrix circuits.

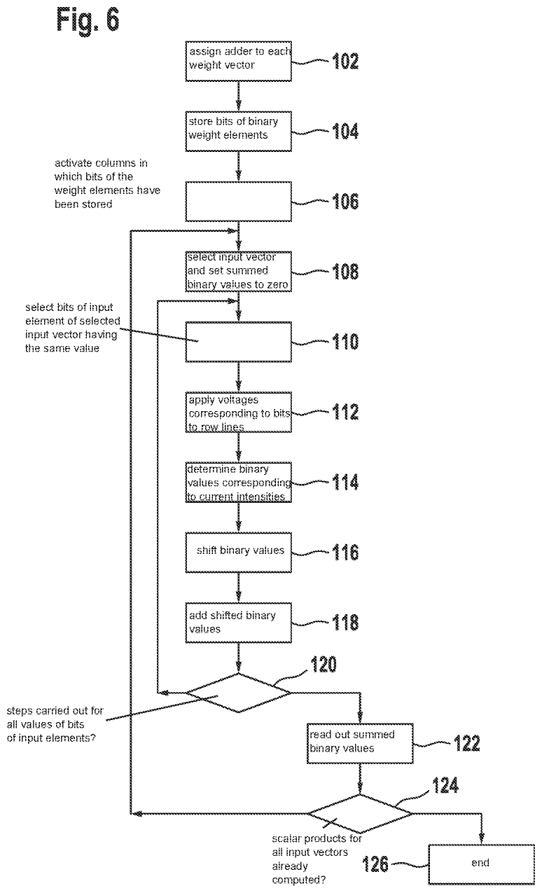

FIG. 6 illustrates a flowchart of a preferred method according to the present invention. In the method, binary scalar products of one or multiple input vectors and one or multiple predetermined weight vectors are computed using a scalar product circuit. The elements of the input vectors and of the weight vectors are in each case in binary form, i.e., given as binary input elements and binary weight elements.

The scalar product circuit includes adders corresponding to the number of predetermined weight vectors, i.e., at least the same number of adders as weight vectors, one or multiple weight ranges that are situated in various matrix circuits of the scalar product circuit when multiple weight ranges are assigned being assigned to each adder, each adder being connected to the bit shifting elements that are connected via the analog-to-digital converters to the bit sections that are included in the weight ranges assigned to the adder. This corresponds to a scalar product circuit as described in conjunction with FIGS. 2 through 4.

In the method, an adder is initially assigned to each weight vector in step 102, and those weight ranges that are assigned to the adder that is assigned to the particular weight vector are subsequently assigned to each weight vector.

The bits of the binary weight elements are stored in step 104. For each weight vector, the bits of the weight elements are stored in memory cells contained in each case in a column of a bit section of a weight range assigned to the weight vector. The bits of a weight element are stored in each case in a row, and the bits of various weight elements of the weight vector that have the same value and that are stored in the same weight range are stored in the same bit section of this weight range. “Storing a bit in a memory cell” means that the memory cell is placed in the first memory state when the bit has the value 0, and the memory cell is placed in the second memory state when the bit has the value 1.

The columns in which bits of the weight elements have been stored are activated in step 106, and the other columns are not activated.

One of the input vectors for which the scalar products are to be computed is subsequently selected, and for this input vector the summed binary values of the adders are set to zero in step 108. The bits of the input elements of the particular selected input vector, having the same value, are selected in step 110.

Voltages corresponding to the bits are applied to the row lines (this may also be referred to as applying bits) in step 112, bits of various input elements being applied to various row lines. A voltage of 0 V is applied when the particular bit has the value 0, and a voltage having the predetermined voltage value is applied when the particular bit has the value 1.

Binary values that correspond to the current intensities of the currents in the activated column lines, as described above, are determined by the analog-to-digital converters in step 114.

These binary values are shifted by the bit shifting units in step 116 in order to obtain shifted binary values, the number of bits by which the binary value is to be shifted being predefined for each bit shifting unit. The predefined number of bits is determined as the sum of the value of the bits of the input elements, corresponding to which voltages are applied, and the value of the bits of the weight elements that are stored in the bit section to which the particular bit shifting unit is connected via the analog-to-digital converter.

The shifted binary values are added by the adders in step 118, it being clear that each adder adds those shifted binary values that are determined and transferred by the bit shifting units that are connected to the particular adder.

It is checked in step 120 whether steps 110 through 118 have already been carried out for all values for the bits of the input elements. If this is not the case, the method continues with step 110 (selection of bits having a certain value), bits having a different value not yet used being selected. If this is the case, the summed binary values are read out in step 122 as binary scalar products of the selected input vector and the weight vector.

It is checked in step 124 whether scalar products for all input vectors have already been computed (steps 108 through 122). If this is not the case, the method continues anew with step 108 (zeroing), an input vector being selected for which the scalar products have not yet been computed. If this is the case, the method is ended in step 126.

As mentioned, further weight vectors may be stored in other columns of the bit sections, the procedure as described above in step 104 being followed when storing these weight vectors. These columns may then be activated in order to form scalar products of these further weight vectors and possibly other input vectors.

1-12. (canceled)

13. A scalar product circuit for computing a binary scalar product of an input vector and a weight vector, comprising:
one or multiple adders that are configured to add received binary values and form a summed binary value; and
at least one matrix circuit including memory cells arranged in multiple rows and multiple columns in the form of a matrix, each memory cell of the memory cells including a first memory state and a second memory state, the matrix circuit including a row line for each row of the rows and a column line for each column of the columns, each memory cell being connected to one row line and to one column line and being configured to conduct an electrical current into the column line connected to the memory cell, a current intensity of the current being a function of a voltage that is present at the row line connected to the memory cell, and of the memory state of the memory cell, the current intensity being equal to zero when a voltage of zero is applied, and the current intensities for the first and the second memory states being different from one another when the applied voltage has a predetermined voltage value not equal to zero;
wherein each matrix circuit of the at least one matrix circuit includes at least one weight range with one or multiple bit sections, each bit section of the bit sections including at least one column of the memory cells, the memory cells within each bit section being configured in such a way that when a voltage having the predetermined voltage value is present at each of the row lines that are connected to the memory cells, and when the memory cells are in the second memory state, the current having the same current intensity is conducted from each memory cell into the column line connected to the memory cell;
wherein the matrix circuit includes, for each bit section, an analog-to-digital converter and a bit shifting unit connected to the analog-to-digital converter, the column lines of the memory cells of the bit section being connected to the analog-to-digital converter, and the analog-to-digital converter being configured to determine a binary value corresponding to the current intensity of a current flowing at an input of the analog-to-digital converter, and to transfer the binary value to the bit shifting unit, each bit shifting unit being configured to shift the bits of the binary value transferred to it by a predefinable number of bits in a direction that arithmetically corresponds to a multiplication by a corresponding power of 2;
wherein, for each column of the memory cells, a column selection switching element is provided which is configured to activate the column, and when the column is activated, a current corresponding to the voltages present at the row lines and to the memory states of the memory cells being provided by the column line to the analog-to-digital converter connected to the column line, and when the column is not activated, no current being provided by the column line to the analog-to-digital converter connected thereto;
wherein, the bit shifting units are connected to one of the adders, in each case those bit shifting units that are included in a weight range being connected to the same adder.

14. The scalar product circuit as recited in claim 13, wherein each of the memory cells is configured in such a way that when the predetermined voltage value is present, the current intensity of the current that is conducted into the column line when the memory cell is in the second memory state is greater, by a multiple, than the current intensity of the current that is conducted into the column line when the memory cell is in the first memory state, the multiple being at least 100.

15. The scalar product circuit according to claim 14, wherein the multiple is at least 1000.

16. The scalar product circuit as recited in claim 13, wherein each of the memory cells is configured in such a way that when the memory cell is in the first state, no current is conducted into the column line connected to the memory cell.

17. The scalar product circuit as recited in claim 13, wherein each of the memory cells includes: i) a memristor, and/or ii) a semiconductor switching element, and/or (iii) a ferroelectric field effect transistor or a field effect transistor with a floating gate.

18. The scalar product circuit as recited in claim 13, wherein multiple matrix circuits are provided, the bit shifting units from one weight range in each case being connected to the same adder in two or more of the matrix circuits.

19. The scalar product circuit as recited in claim 13, wherein for each row line, a voltage generation element is provided which is connected to the row line and configured, as a function of a predefined input signal which may be present in two different value ranges, to generate a voltage of 0 V or a voltage having the predetermined voltage value and apply it to the row line.

20. The scalar product circuit as recited in claim 13, wherein the analog-to-digital converters are configured to determine the binary values using 5 bits or fewer.

21. A method for computing binary scalar products of one or multiple input vectors, each including binary input elements, and one or multiple predetermined first weight vectors, each including binary weight elements, using a scalar product circuit including:
one or multiple adders that are configured to add received binary values and form a summed binary value, and
at least one matrix circuit including memory cells arranged in multiple rows and multiple columns in the form of a matrix, each memory cell of the memory cells including a first memory state and a second memory state, the matrix circuit including a row line for each row of the rows and a column line for each column of the columns, each memory cell being connected to one row line and to one column line and being configured to conduct an electrical current into the column line connected to the memory cell, a current intensity of the current being a function of a voltage that is present at the row line connected to the memory cell, and of the memory state of the memory cell, the current intensity being equal to zero when a voltage of zero is applied, and the current intensities for the first and the second memory states being different from one another when the applied voltage has a predetermined voltage value not equal to zero,
wherein each matrix circuit of the at least one matrix circuit includes at least one weight range with one or multiple bit sections, each bit section of the bit sections including at least one column of the memory cells, the memory cells within each bit section being configured in such a way that when a voltage having the predetermined voltage value is present at each of the row lines that are connected to the memory cells, and when the memory cells are in the second memory state, the current having the same current intensity is conducted from each memory cell into the column line connected to the memory cell,
wherein the matrix circuit includes, for each bit section, an analog-to-digital converter and a bit shifting unit connected to the analog-to-digital converter, the column lines of the memory cells of the bit section being connected to the analog-to-digital converter, and the analog-to-digital converter being configured to determine a binary value corresponding to the current intensity of a current flowing at an input of the analog-to-digital converter, and to transfer the binary value to the bit shifting unit, each bit shifting unit being configured to shift the bits of the binary value transferred to it by a predefinable number of bits in a direction that arithmetically corresponds to a multiplication by a corresponding power of 2,
wherein, for each column of the memory cells, a column selection switching element is provided which is configured to activate the column, and when the column is activated, a current corresponding to the voltages present at the row lines and to the memory states of the memory cells being provided by the column line to the analog-to-digital converter connected to the column line, and when the column is not activated, no current being provided by the column line to the analog-to-digital converter connected thereto,
wherein, the bit shifting units are connected to one of the adders, in each case those bit shifting units that are included in a weight range being connected to the same adder,
wherein the number of the adders of the scalar product circuit correspond to the number of the predetermined first weight vectors, one or multiple of the weight ranges that are situated in the at least at least one matrix circuit of the scalar product circuit when multiple weight ranges are assigned, being assigned to each of the adders, each of the adders being connected to the bit shifting elements that are connected via the analog-to-digital converters to the bit sections included in the weight ranges assigned to the adder, the method comprising the following steps:
A) assigning an adder of the adders to each first weight vector of the first weight vectors, and assigning the weight ranges that are assigned to the adder to the weight vector to which the adder is assigned;
B) storing bits of the binary weight elements of the first weight vectors, for each of the first weight vector, the bits of the binary weight elements of the weight vector being stored in the memory cells that are contained in each case in a column of a bit section of a weight range that is assigned to the weight vector, each of the bits of a weight element of the binary weight elements being stored in a row, bits of various weight elements of the weight vector that have the same value and that are stored in the same weight range being stored in the same bit section of this weight range, and when a bit is stored in a memory cell, the memory cell being placed in the first memory state when the bit has the value 0, and the memory cell being placed in the second memory state when the bit has the value 1;
C) activating the columns of memory cells in which bits of the weight elements of the first weight vectors have been stored;
D) for at least one of the input vectors:
a) setting summed binary values of the adders to zero;
b) for the bits of the input elements of the input vector having the same value, in each case:
i) applying voltages corresponding to the bits to the row lines, voltages corresponding to the bits of various input elements being applied to various row lines, a voltage of 0 V being applied when the particular bit has the value 0, and a voltage having the predetermined voltage value being applied when the particular bit has the value 1;
ii) determining binary values by the analog-to-digital converters;
iii) shifting the binary values by the bit shifting units in order to obtain shifted binary values, the number of bits by which the binary value is to be shifted being predefined for each bit shifting unit, the predefined number of bits being determined as a sum of the value of the bits of the input elements, corresponding to which voltages are applied, and of the value of the bits of the weight elements that are stored in the bit section to which the bit shifting unit is connected via the analog-to-digital converter;
iv) adding the shifted binary values by the adders;
c) reading out the summed binary values as first binary scalar products.

22. The method as recited in claim 21, wherein second binary scalar products of the one or multiple input vectors and one or multiple predetermined second weight vectors which in each case include binary weight elements are computed, the number of second weight vectors being less than or equal to the number of first weight vectors, including:
E) assigning an adder of the adders to each second weight vector, and assigning the weight ranges that are assigned to the adder to the weight vector to which the adder is assigned;
F) storing bits of the binary weight elements of the second weight vectors, for each of the second weight vectors, the procedure corresponding to step B) being carried out, the bits of the weight elements of the second weight vectors being stored in columns that are different from the columns in which the bits of the weight elements of the first weight vectors are stored;
G) activating the columns in which bits of the weight elements of the second weight vectors have been stored;
H) for at least one of the input vectors, carrying out the substeps of step D), except that in substep c) the summed binary values are read out as second scalar products.

23. A module, comprising:
a scalar product circuit, including:
one or multiple adders that are configured to add received binary values and form a summed binary value, and
at least one matrix circuit including memory cells arranged in multiple rows and multiple columns in the form of a matrix, each memory cell of the memory cells including a first memory state and a second memory state, the matrix circuit including a row line for each row of the rows and a column line for each column of the columns, each memory cell being connected to one row line and to one column line and being configured to conduct an electrical current into the column line connected to the memory cell, a current intensity of the current being a function of a voltage that is present at the row line connected to the memory cell, and of the memory state of the memory cell, the current intensity being equal to zero when a voltage of zero is applied, and the current intensities for the first and the second memory states being different from one another when the applied voltage has a predetermined voltage value not equal to zero,
wherein each matrix circuit of the at least one matrix circuit includes at least one weight range with one or multiple bit sections, each bit section of the bit sections including at least one column of the memory cells, the memory cells within each bit section being configured in such a way that when a voltage having the predetermined voltage value is present at each of the row lines that are connected to the memory cells, and when the memory cells are in the second memory state, the current having the same current intensity is conducted from each memory cell into the column line connected to the memory cell,
wherein the matrix circuit includes, for each bit section, an analog-to-digital converter and a bit shifting unit connected to the analog-to-digital converter, the column lines of the memory cells of the bit section being connected to the analog-to-digital converter, and the analog-to-digital converter being configured to determine a binary value corresponding to the current intensity of a current flowing at an input of the analog-to-digital converter, and to transfer the binary value to the bit shifting unit, each bit shifting unit being configured to shift the bits of the binary value transferred to it by a predefinable number of bits in a direction that arithmetically corresponds to a multiplication by a corresponding power of 2,
wherein, for each column of the memory cells, a column selection switching element is provided which is configured to activate the column, and when the column is activated, a current corresponding to the voltages present at the row lines and to the memory states of the memory cells being provided by the column line to the analog-to-digital converter connected to the column line, and when the column is not activated, no current being provided by the column line to the analog-to-digital converter connected thereto,
wherein, the bit shifting units are connected to one of the adders, in each case those bit shifting units that are included in a weight range being connected to the same adder; and
a processing unit connected to the scalar product circuit and configured to compute binary scalar products of one or multiple input vectors, each including binary input elements, and one or multiple predetermined first weight vectors, each including binary weight elements, using the scalar product circuit, wherein the number of the adders of the scalar product circuit correspond to the number of the predetermined first weight vectors, one or multiple of the weight ranges that are situated in the at least at least one matrix circuit of the scalar product circuit when multiple weight ranges are assigned, being assigned to each of the adders, each of the adders being connected to the bit shifting elements that are connected via the analog-to-digital converters to the bit sections included in the weight ranges assigned to the adder, and the processing unit is configured to:
A) assign an adder of the adders to each first weight vector of the first weight vectors, and assigning the weight ranges that are assigned to the adder to the weight vector to which the adder is assigned;
B) store bits of the binary weight elements of the first weight vectors, for each of the first weight vector, the bits of the binary weight elements of the weight vector being stored in the memory cells that are contained in each case in a column of a bit section of a weight range that is assigned to the weight vector, each of the bits of a weight element of the binary weight elements being stored in a row, bits of various weight elements of the weight vector that have the same value and that are stored in the same weight range being stored in the same bit section of this weight range, and when a bit is stored in a memory cell, the memory cell being placed in the first memory state when the bit has the value 0, and the memory cell being placed in the second memory state when the bit has the value 1;
C) activate the columns of memory cells in which bits of the weight elements of the first weight vectors have been stored;
D) for at least one of the input vectors:
a) set summed binary values of the adders to zero;
b) for the bits of the input elements of the input vector having the same value, in each case:
i) apply voltages corresponding to the bits to the row lines, voltages corresponding to the bits of various input elements being applied to various row lines, a voltage of 0 V being applied when the particular bit has the value 0, and a voltage having the predetermined voltage value being applied when the particular bit has the value 1;
ii) determine binary values by the analog-to-digital converters;
iii) shift the binary values by the bit shifting units in order to obtain shifted binary values, the number of bits by which the binary value is to be shifted being predefined for each bit shifting unit, the predefined number of bits being determined as a sum of the value of the bits of the input elements, corresponding to which voltages are applied, and of the value of the bits of the weight elements that are stored in the bit section to which the bit shifting unit is connected via the analog-to-digital converter;
iv) add the shifted binary values by the adders;
c) read out the summed binary values as first binary scalar products.

24. A non-transitory machine-readable memory medium on which is stored a computer program for computing binary scalar products of one or multiple input vectors, each including binary input elements, and one or multiple predetermined first weight vectors, each including binary weight elements, using a scalar product circuit including:
one or multiple adders that are configured to add received binary values and form a summed binary value, and
at least one matrix circuit including memory cells arranged in multiple rows and multiple columns in the form of a matrix, each memory cell of the memory cells including a first memory state and a second memory state, the matrix circuit including a row line for each row of the rows and a column line for each column of the columns, each memory cell being connected to one row line and to one column line and being configured to conduct an electrical current into the column line connected to the memory cell, a current intensity of the current being a function of a voltage that is present at the row line connected to the memory cell, and of the memory state of the memory cell, the current intensity being equal to zero when a voltage of zero is applied, and the current intensities for the first and the second memory states being different from one another when the applied voltage has a predetermined voltage value not equal to zero,
wherein each matrix circuit of the at least one matrix circuit includes at least one weight range with one or multiple bit sections, each bit section of the bit sections including at least one column of the memory cells, the memory cells within each bit section being configured in such a way that when a voltage having the predetermined voltage value is present at each of the row lines that are connected to the memory cells, and when the memory cells are in the second memory state, the current having the same current intensity is conducted from each memory cell into the column line connected to the memory cell,
wherein the matrix circuit includes, for each bit section, an analog-to-digital converter and a bit shifting unit connected to the analog-to-digital converter, the column lines of the memory cells of the bit section being connected to the analog-to-digital converter, and the analog-to-digital converter being configured to determine a binary value corresponding to the current intensity of a current flowing at an input of the analog-to-digital converter, and to transfer the binary value to the bit shifting unit, each bit shifting unit being configured to shift the bits of the binary value transferred to it by a predefinable number of bits in a direction that arithmetically corresponds to a multiplication by a corresponding power of 2,
wherein, for each column of the memory cells, a column selection switching element is provided which is configured to activate the column, and when the column is activated, a current corresponding to the voltages present at the row lines and to the memory states of the memory cells being provided by the column line to the analog-to-digital converter connected to the column line, and when the column is not activated, no current being provided by the column line to the analog-to-digital converter connected thereto,
wherein, the bit shifting units are connected to one of the adders, in each case those bit shifting units that are included in a weight range being connected to the same adder,
wherein the number of the adders of the scalar product circuit correspond to the number of the predetermined first weight vectors, one or multiple of the weight ranges that are situated in the at least at least one matrix circuit of the scalar product circuit when multiple weight ranges are assigned, being assigned to each of the adders, each of the adders being connected to the bit shifting elements that are connected via the analog-to-digital converters to the bit sections included in the weight ranges assigned to the adder, the computer program, when executed by a processor, causing the processor to perform the following steps:
A) assigning an adder of the adders to each first weight vector of the first weight vectors, and assigning the weight ranges that are assigned to the adder to the weight vector to which the adder is assigned;
B) storing bits of the binary weight elements of the first weight vectors, for each of the first weight vector, the bits of the binary weight elements of the weight vector being stored in the memory cells that are contained in each case in a column of a bit section of a weight range that is assigned to the weight vector, each of the bits of a weight element of the binary weight elements being stored in a row, bits of various weight elements of the weight vector that have the same value and that are stored in the same weight range being stored in the same bit section of this weight range, and when a bit is stored in a memory cell, the memory cell being placed in the first memory state when the bit has the value 0, and the memory cell being placed in the second memory state when the bit has the value 1;
C) activating the columns of memory cells in which bits of the weight elements of the first weight vectors have been stored;
D) for at least one of the input vectors:
a) setting summed binary values of the adders to zero;
b) for the bits of the input elements of the input vector having the same value, in each case:
i) applying voltages corresponding to the bits to the row lines, voltages corresponding to the bits of various input elements being applied to various row lines, a voltage of 0 V being applied when the particular bit has the value 0, and a voltage having the predetermined voltage value being applied when the particular bit has the value 1;
ii) determining binary values by the analog-to-digital converters;
iii) shifting the binary values by the bit shifting units in order to obtain shifted binary values, the number of bits by which the binary value is to be shifted being predefined for each bit shifting unit, the predefined number of bits being determined as a sum of the value of the bits of the input elements, corresponding to which voltages are applied, and of the value of the bits of the weight elements that are stored in the bit section to which the bit shifting unit is connected via the analog-to-digital converter;
iv) adding the shifted binary values by the adders;
c) reading out the summed binary values as first binary scalar products.
